(19) United States
(12) Patent Application Publication
(10) Pub. No.: US 2016/0081225 A1
(43) Pub. Date: Mar. 17, 2016

(54) STACKABLE ROTATED HEAT SINK

(71) Applicant: Molex, LLC, Lisle, IL (US)

(72) Inventors: Kousuke Taketomi, Yamato (JP); Rinkou Fukunaga, Kagoshima (JP)

(73) Assignee: Molex, LLC, Lisle, IL (US)

(21) Appl. No.: 14/946,973

(22) Filed: Nov. 20, 2015

Related U.S. Application Data
(63) Continuation of application No. 13/864,409, filed on Apr. 17, 2013.

(30) Foreign Application Priority Data
Apr. 17, 2012 (JP) 2012-094163

(51) Int. Cl. H05K 7/20

(52) U.S. Cl. CPC H05K 7/20418

(57) ABSTRACT

A cooling assembly is provided which has a heat-transferring member, a heat sink assembly, and a plurality of heat-transferring columns. The heat-transferring member has first and second sides and the first side of the heat-transferring member is configured for attachment to a heat-generating body. The heat sink assembly includes first and second heat sinks provided in a stacked configuration. The first heat sink is between the second side and the second heat sink. Each of the first and second heat sinks has first and second support portions. Each of the first and second support portions has fins extending therefrom. The second heat sink is provided at an offset angle relative to the first heat sink. Each heat-transferring column extends from the second side of the heat-transferring member. Each heat-transferring column is configured to engage the heat sink assembly and to support the heat sink assembly relative to the heat-transferring member.

### REFERENCE TO RELATED APPLICATIONS

The Present Disclosure is a continuation of prior-filed U.S. patent application Ser. No. 13/864,409, entitled “Stackable Rotated Heat Sink,” filed on 17 Apr. 2013 which, in turn, claims priority to prior-filed Japanese Patent Application No. 2012-094163, entitled “Cooling Device,” filed on 17 Apr. 2012 with the Japanese Patent Office. The content of the aforementioned patent applications are incorporated in their entireties herein.

### BACKGROUND OF THE PRESENT DISCLOSURE

The Present Disclosure relates, generally, to a cooling device including a heat sink.

A cooling device has been disclosed in Japanese Patent Application No. 2008-134115, which is used to radiate the heat of a heat-generating body in an electronic device. In this cooling device, a plurality of overlapping heat sinks (comb-shaped fins in the '115 application) are arranged, and these are connected by a column-shaped base pin which transfers the heat.

In the '115 application, a plurality of fins extend radially from a single base pin in each heat sink. Because it is difficult to increase the number of base pins using this structure, it is difficult to improve the heat transfer efficiency from the heat-generating body to the heat sinks.

### SUMMARY OF THE PRESENT DISCLOSURE

A purpose of the Present Disclosure is to provide a cooling device able to improve the efficiency with which heat is transferred from a heat-generating body to a heat sink.

In the cooling device of the Present Disclosure, a heat-transferring member is mounted on one side of a panel-shaped heat-generating body. A heat sink is arranged farther away from the heat-generating body than the heat-transferring member in the thickness direction of the heat-generating body. The heat sink includes a plurality of fins extending in the direction of the heat-generating body and separated from each other by a space, and a support portion extending in the direction of the fins, and connecting to and supporting the fins. A plurality of heat-transferring columns is connected to the heat-transferring member and separated from each other by a space, with the heat-transferring columns each extending in the thickness direction of the heat-generating body and connecting to the support portion. In this way, the efficiency with which heat is transferred from a heat-generating body to a heat sink can be improved.

In one aspect of the Present Disclosure, the cooling may further comprise a plurality of heat sinks arranged in the thickness direction of the heat-generating body with each functioning as a heat sink. In this way, the cooling performance of the cooling device can be improved.

In one aspect of the Present Disclosure, each of the plurality of heat sinks may have the same shape. In this way, the manufacturing productivity of the cooling device can be improved.

In one aspect of the Present Disclosure, each of the plurality of heat sinks may be offset in the circumferential direction with respect to the adjacent heat sinks and centered on the centerline of the heat-generating body in the thickness direction. In this way, the air receiving heat from the heat-generating body in each portion of the heat sinks may be discharged more readily.

In one aspect of the Present Disclosure, the support portion for each of the plurality of heat sinks may include a first extended portion extending in the direction of the heat-generating body and a second extended portion extending in a direction intersecting the direction of extension of the first extended portion. Also, each of the plurality of heat sinks may include, as the plurality of fins, a plurality of fins projecting from the first extended portion, and a plurality of fins projecting from the second extended portion. In this way, the cooling performance of the cooling device can be improved.

In one aspect of the Present Disclosure, the support portion for each of the plurality of heat sinks may include, as the second extended portion, at least two extended portions arranged symmetrically with respect to the centerline of the first extended portion. In this way, the cooling performance of the cooling device can be improved.

In one aspect of the Present Disclosure, the plurality of heat-transferring columns may include at least three heat-transferring columns, the support portion may include at least three connecting portions connected to at least three heat-transferring columns, and at least three connecting portions may be arranged at equal intervals in the circumferential direction centered on the centerline of the heat-generating body in the thickness direction. In a structure in which a plurality of heat sinks are offset in the circumferential direction, each of the heat-transferring columns can be connected to all of the heat sinks.

In one aspect of the Present Disclosure, each of the plurality of heat sinks may include a first half body having a support portion and a plurality of fins, and a second half body having a support portion and a plurality of fins. Here, the first half body and the second half body may be arranged symmetrically with respect to a straight line running along the heat-generating body. This allows the size of each heat sink to be increased. As a result, the cooling performance of the cooling device can be improved.

In one aspect of the Present Disclosure, an air passage may be formed between the first half body and the second half body, and the air passage may extend radially from the centerline running through the heat-generating body in the thickness direction and be connected to the outer side of the plurality of heat sinks. In this way, the air can be sent through an air passage between the first half body and the second half body, which further improves cooling performance.

In one aspect of the Present Disclosure, the plurality of fins in the first half body may extend in the direction of the second half body, the plurality of fins in the second half body may extend in the direction of the first half body, and the air passage may be formed between the plurality of fins of the first half body and the plurality of fins of the second half body. In this way, the air can be sent to the fins through the air passage between the first half body and the second half body, which further improves cooling performance.

### BRIEF DESCRIPTION OF THE FIGURES

The organization and manner of the structure and operation of the Present Disclosure, together with further objects and advantages thereof, may best be understood by reference to the following Detailed Description, taken in connection with the accompanying Figures, wherein like reference numerals identify like elements, and in which:

FIG. 1 is a perspective view of the cooling device of the Present Disclosure;

FIG. 2 is a perspective view of the cooling device of FIG. 1, where a section of the heat sink half body has been removed for ease in viewability;

FIG. 3 is a side view of the lighting device containing the cooling device of FIG. 1;

FIG. 4 is a top view of the heat sink constituting the cooling device of FIG. 1;

FIG. 5 is a bottom view of the cooling device of FIG. 1;

FIG. 6 is a perspective view of a heat sink of the Present Disclosure, in which a plurality of heat sinks are arranged in the thickness direction of the circuit board; and

FIG. 7 is a top view of the heat sinks shown in FIG. 6.

### DESCRIPTION OF THE PREFERRED EMBODIMENTS

While the Present Disclosure may be susceptible to embodiment in different forms, there is shown in the Figures, and will be described herein in detail, specific embodiments, with the understanding that the Present Disclosure is to be considered an exemplification of the principles of the Present Disclosure, and is not intended to limit the Present Disclosure to that as illustrated.

As such, references to a feature or aspect are intended to describe a feature or aspect of an example of the Present Disclosure, not to imply that every embodiment thereof must have the described feature or aspect. Furthermore, it should be noted that the description illustrates a number of features. While certain features have been combined together to illustrate potential system designs, those features may also be used in other combinations not expressly disclosed. Thus, the depicted combinations are not intended to be limiting, unless otherwise noted.

In the embodiments illustrated in the Figures, representations of directions such as up, down, left, right, front and rear, used for explaining the structure and movement of the various elements of the Present Disclosure, are not absolute, but relative. These representations are appropriate when the elements are in the position shown in the Figures. If the description of the position of the elements changes, however, these representations are to be changed accordingly.

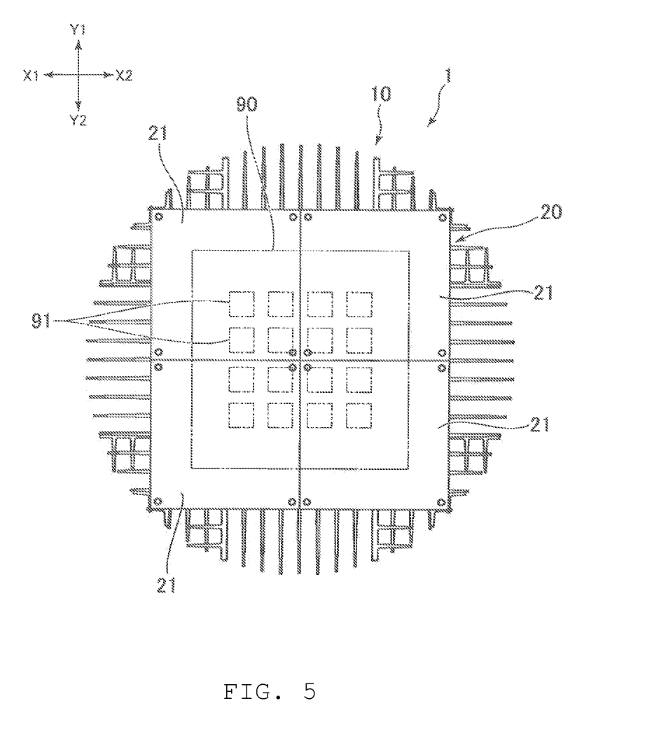

Referring to the Figures, and, specifically, as shown in FIG. 5, the cooling device 1 has a heat-transferring member 20 in the bottom portion. In this example, the heat-transferring member 20 has a plurality of heat-dissipating plates 21. In this example, four heat-dissipating plates 21 are arranged on the same plane, and together constitute a rectangular heat-transferring member 20. The heat-dissipating plates of the heat-transferring member 20 do not have to be divided into four heat-dissipating plates 21. The heat-transferring member 20 may have any number of heat-dissipating plates corresponding to the size of the four heat-dissipating plates 21. The heat-dissipating plates 21 can be metal plates made of a thermally conductive metal. Coolant passages may also be formed so that coolant may circulate inside these containers.

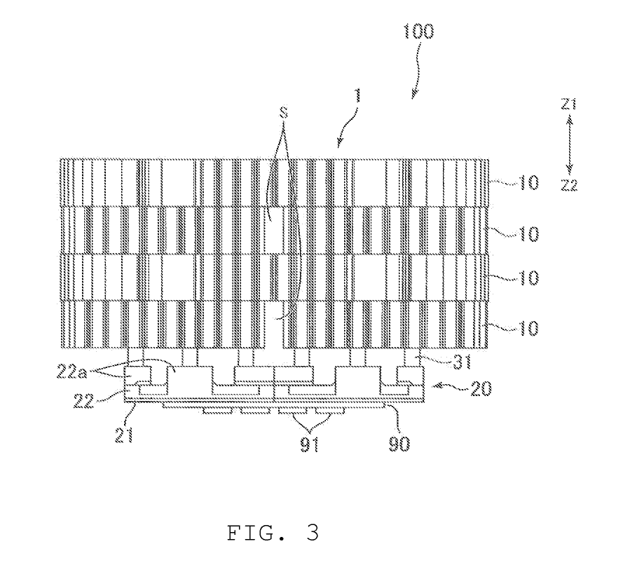

The heat-transferring member 20 may be mounted on one side of a panel-shaped heat-generating body such as an integrated circuit, a printed circuit board on which integrated circuits have been mounted, an IC chip, or an active/passive element. In the example explained here and shown in FIG. 3, the heat-generating body is a circuit board 90, and the heat-transferring member 20 is mounted on one side of the circuit board 90. A plurality of electronic components are mounted on the other side of the circuit board 90. The cooling device 1 in this example is a device used in a lighting device 100. Here, a plurality of Light Emitting Diodes (LEDs) 91 are mounted on the circuit board 90. As shown in FIG. 5, the LEDs 91 are arranged in a grid-like pattern and are positioned in the central portion of the heat-transferring member 20. The heat from the LEDs 91 is dissipated by the heat-dissipating plates 21 in the entire heat-transferring member 20. In the lighting device 100 shown in FIG. 3, the light from the LEDs 91 is directed downward. The electronic components are not limited to LEDs. For example, the electronic components can be light-emitting bodies such as incandescent lamps. Here, other components such as integrated circuits may be mounted on the circuit board 90.

As shown in FIG. 3, the cooling device 1 has a heat sink 10. The heat sink 10 is arranged so as to be farther away from the circuit board 90 than the heat-transferring member 20 in the thickness direction of the circuit board 90 (direction Z1-Z2 in the Figure). In other words, the heat sink 10 is arranged on the other side of the interposed heat-transferring member 20 from the circuit board 90. In this example, the cooling device 1 has a plurality of heat sinks 10. These heat sinks 10 are arranged away from the heat-transferring member 20 in the thickness direction of the circuit board 90. As a result, air can flow towards the heat sinks 10 through the space between the heat sinks 10 and the heat-transferring member 20. As mentioned above, the cooling device 1 used in the lighting device 100 has the heat-transferring member 20 on the bottom end. As a result, the warm air inside the heat sinks 10 is directed upwards.

As shown in FIG. 3, the cooling device 1 in this example has four heat sinks 10. The four heat sinks 10 are arranged in the thickness direction of the circuit board 90 (that is, in the thickness direction of the heat-dissipating plates 21, or direction Z1-Z2). The two adjacent heat sinks 10 make contact with each other so that there is no space between the four heat sinks 10. Space may also be formed between the four heat sinks 10. Moreover, the number of heat sinks 10 is not limited to four.

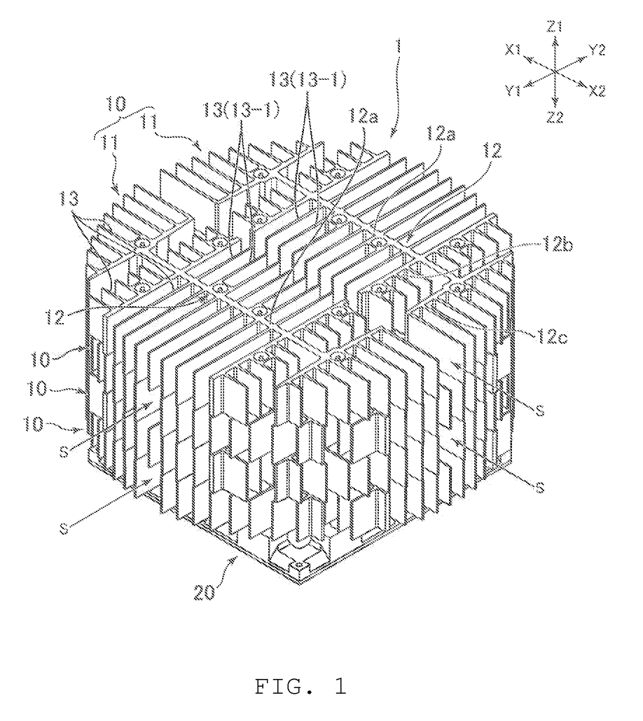

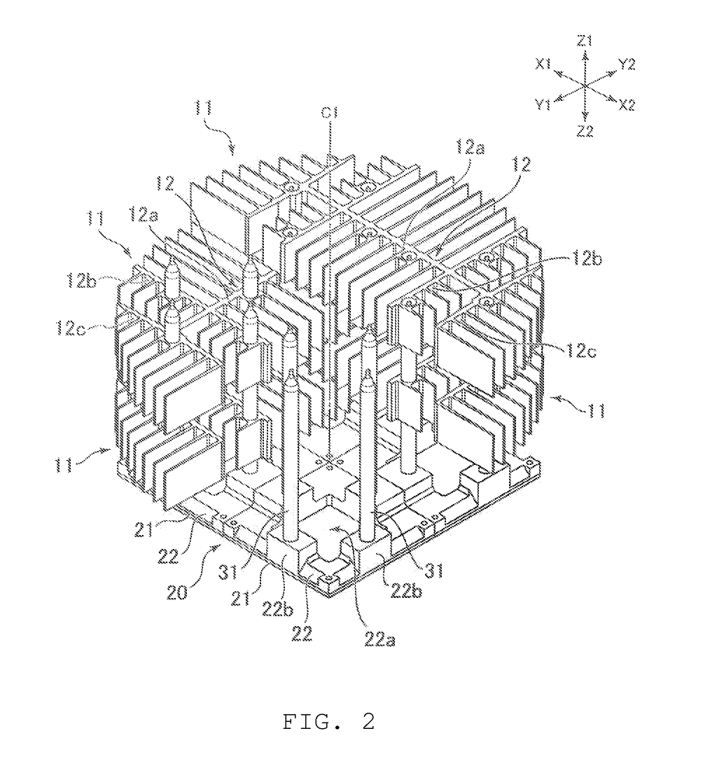

As shown in FIGS. 1-2, each heat sink 10 has a support portion 12 and a plurality of fins 13. The fins 13 in this example are wall-like and are erected on a plane parallel to the circuit board 90. Each fin 13 extends in the direction of the circuit board 90. In this example, each fin 13 extends linearly in a direction parallel to the circuit board 90.

A space is formed between each of the plurality of fins 13, and the support portion 12 extends in the arrangement direction of the fins 13 and is connected to them. In this way, the plurality of fins 13 are supported by the support portion 12. Like the fins 13, the support portion 12 is wall-like and is erected on a plane parallel to the circuit board 90. In other words, the support portion 12 is wall-like and has vertical lines that are parallel to the circuit board 90. Each of the fins 13 projects from the side face of the support portion 12, and is formed orthogonally with respect to the support portion 12.

As explained below and as shown in FIGS. 1-2, the support portion 12 in this example has a portion extending in direction X1-X2, which is orthogonal with respect to the thickness direction of the circuit board 90 (direction Z1-Z2), and a portion extending in direction Y1-Y2, which is orthogonal to direction Z1-Z2 and direction X1-X2. For example, the support portion 12 of the uppermost heat sink 10 has a first extended portion 12a extending in direction X1-X2, and second extended portions 12b, 12c extending in direction Y1-Y2. A plurality of fins 13 is formed in each of the extended portions 12a-12c. Therefore, each heat sink 10 includes fins 13 extending in direction X1-X2 and fins 13 extending in direction Y1-Y2. The fins 13 are formed so that the entire heat sink 10 has a circular shape. The shape of the heat sinks 10 is not limited to a circular shape. They may also be rectangular. The four heat sinks 10 have the same shape. As explained below, two adjacent heat sinks 10 are arranged at a 90° angle with respect to each other in the circumferential direction with reference to the centerline C1.

As shown in FIG. 2, the cooling device 1 has heat-transferring columns for transferring heat. The cooling device 1 has a plurality of heat-transferring columns, and these are arranged apart from each other. The heat-transferring columns in the example explained here are heat pipes 31. The heat-transferring columns do not have to be heat pipes. The heat-transferring columns can be any column-shaped member made of a thermally conductive material such as copper or aluminum.

As shown in FIG. 2, each heat pipe 31 is connected to the heat-transferring member 20. In this example, the heat-transferring member 20 has a plurality of sockets 22 each of which is attached to a heat-dissipating plate 21. The heat pipes 31 are connected thermally to the heat-dissipating plates 21 via these sockets 22. More specifically, each socket 22 is a hole formed at a position corresponding to a heat pipe 31. The end portion of each heat pipe 31 is inserted into a hole. The end portion of the heat pipe 31 is mounted in the socket 22 using solder or an adhesive, or is forcibly inserted. The sockets 22 are attached to heat-dissipating plates 21 using, for example, screws. The sockets 22 may also be attached to heat-dissipating plates 21 using solder or an adhesive.

As shown in FIG. 2, the sockets 22 in this example are frame-shaped with a hole 22a formed on the inside. Also, each socket 22 has protruding portions 22b positioned away from each other, and a hole is formed in each protruding portion 22b for the insertion of a heat pipe 31. In other words, there is a recessed portion between two protruding portions 22b for the mounting of two heat pipes 31. In this way, air can flow to the heat sinks 10 via the recess between the two protruding portions 22b. In this example, the sockets 22 are rectangular, and sized in accordance with the heat-dissipating plates 21. Protruding portions 22b are formed on the four sides of the sockets 22. The sockets 22 may also be integrally molded with the heat-dissipating plates 21.

As shown in FIG. 2, each heat pipe 31 extends in the thickness direction of the circuit board 90 and is connected to the support portion 12 for four heat sinks 10. In other words, each heat pipe 31 is connected to the support portion 12 for four heat sinks 10. In this way, heat from the LEDs 91 is transmitted to the support portion 12 via the heat-dissipating plates 21, the sockets 22, and the heat pipes 31. In other words, the heat from the LEDs 91 is distributed to four heat sinks 10. The heat is then transferred to the fins 13 via the support portion 12.

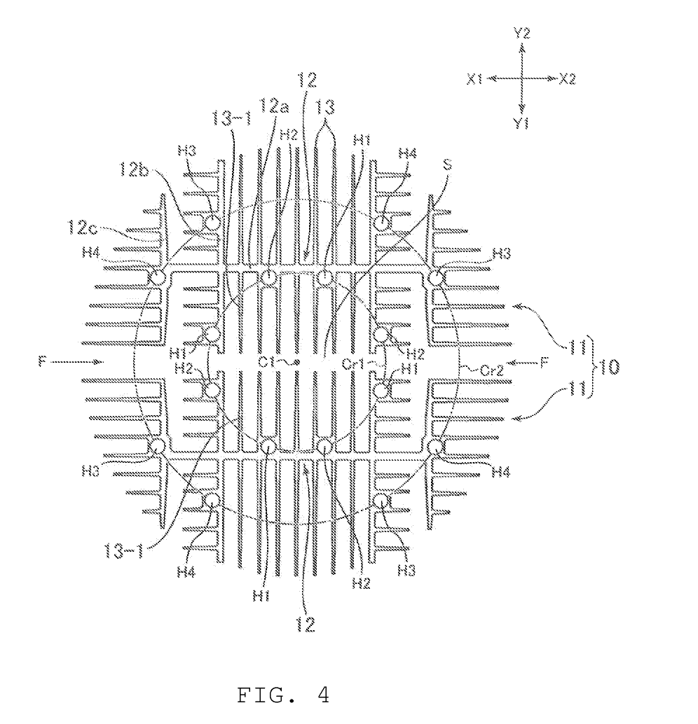

In this example, as shown in FIG. 4, a connecting hole H is formed in the support portion 12 through each heat sink 10 in the thickness direction of the circuit board 90, and a heat pipe 31 is passed through each connecting hole H. In FIG. 4, numbers 1-4 are appended to H denoting connecting holes. Here H1 through H4 are used to indicate specific connecting holes. In other situations, the connecting holes are denoted simply by the letter H. The heat pipes 31 are fixed to the support portion 12 using solder, an adhesive, or forcible insertion. The heat pipes 31 are tube-shaped members that are closed at both ends to seal a coolant inside. In this example, the heat pipes 31 are linear. These are easier to manufacture and cost less than bent heat pipes.

As shown in FIG. 4, each heat sink 10 includes two separate heat sink half bodies 11. These heat sink half bodies 11 are referred to below as heat sink half bodies. Each heat sink half body 11 has the support bodies 12 and fins 13 described above. Two heat sink half bodies 11 constituting a single heat sink 10 are arranged on the same plane. In other words, the two heat sink half bodies 11 are positioned at the same distance from the heat-transferring member 20. An air passage S is formed between the two heat sink half bodies 11 which extends in the direction of the plane on which the half portions are arranged (in the direction of the circuit board 90) and is linked to the outside of the heat sinks 10. In other words, a space is formed between the two heat sink half bodies 11, and this space functions as the air passage S. In this way, air F can be sent into heat sink 10 via the air passage S.

In this example, the heat sinks 10 are divided into two heat sink half bodies 11. In other words, as shown in FIG. 4, the two heat sink half bodies 11 are not linked. As a result, both ends of the two air passages S are open to the outside of the heat sink 10. In this way, air can be efficiently sent to the various portions of the heat sink 10. Also, the air passages S travel along the centerline C1 of the heat sink 10 extending in the thickness direction of the circuit board 90. As a result, air can be sent to the portions of the heat sink 10 near the centerline C1.

In this example, the eight heat sink half bodies 11 constituting the four heat sinks 10 have the same shape. This improves the manufacturing productivity of the heat sinks 10. Because the two heat sink half bodies 11 constituting a single heat sink 10 are divided, the heat sink 10 is easy to manufacture even when the heat sink is large. The two heat sink half bodies 11 constituting a single heat sink 10 are arranged symmetrically along the centerline C1 and a line orthogonal to the centerline C1. Each heat sink half body 11 is an integrally molded member. The heat sink half bodies 11 can be extrusion molded or cast in the thickness direction of the circuit board 90.

The four heat sinks 10 are offset in the circumferential direction with respect to adjacent heat sinks 10 and are centered on the centerline C1. In this example, as shown in FIGS. 1-2, two adjacent heat sinks 10 are arranged at 90° angles to each other in the circumferential direction with respect to the centerline C1. As a result, the air flowing upward from the heat-transferring member 20 is easily distributed to each portion of the fins 13, and the cooling performance can be improved. In this example, an air passage S is formed between the two heat sink half bodies 11 constituting a single heat sink 10. Because the two adjacent heat sinks 10 are offset in the circumferential direction, the air passages S do not overlap in the thickness direction of the circuit board 90. As a result, the air flowing into an air passage S is also supplied to the fins 13 of the adjacent heat sink 10, and the fins 13 can be cooled more efficiently. The offset angle of the heat sinks 10 is not limited to 90°. For example, the offset angle can be 45° or 120° as described below. The angle can be altered based on the structure of the heat sink half bodies 11.

As mentioned above, a plurality of connecting holes H are formed in the heat sinks 10 for insertion of heat pipes 31. As shown in FIG. 4, the positions of the connection holes H are laid out so as to be rotationally symmetrical to the centerline C1. In other words, the connecting holes H are positioned along a circle centered on the centerline C1 at the offset angle of the two adjacent heat sinks 10 (90° in this example). In this way, the four heat sinks 10 can have the same shape, and each heat pipe 31 can be connected to the four heat sinks 10. In this example and as shown in FIG. 4, the four connecting holes H1 are arranged on circle Cr1 at 90° intervals. Another four connecting holes H2 are arranged on circle Cr1 at 90° intervals. Connecting holes H3 and H4 are arranged on circle Cr2 which has a larger diameter than circle Cr1 which includes connecting holes H1 and H2. Four connecting holes H3 are arranged at 90° intervals, and four connecting holes H4 are arranged at 90° intervals. The support portion 12 is formed so as to pass through the positions of connecting holes H1-H4 (the positions of the heat pipes 31). The heat sink half bodies 11 can be arranged at the desired angle, which is a multiple of 90°, in accordance with the layout of the connecting holes H1-H4.

As shown in FIG. 1, the support portion 12 includes a first extended portion 12a. As mentioned above, in this example, two adjacent heat sinks 10 are arranged at a 90° angle with respect to each other in the circumferential direction from the centerline C1. As a result, the first extended portion 12a in one heat sink 10 of the two heat sinks 10 extends in the X1-X2 direction, and the first extended portion 12a of the other heat sink 10 extends in the Y1-Y2 direction (see FIG. 2). The first extended portion 12a is a slender wall-shaped member erected on a plane parallel to the circuit board 90, and a line orthogonal to the extended portion is parallel to the circuit board 90.

As explained above, a single heat sink 10 has two heat sink half bodies 11. As shown in FIG. 4, the first extended portions 12a face each other with the centerline C1 interposed between them. A plurality of fins 13 arranged in the extension direction of the first extended portion 12a are formed on both side surfaces of the first extended portion 12a. The plurality of fins 13 extend from the first extended portion 12a towards the heat sink half body 11 on the opposite side (the fins denoted by 13-1 in FIGS. 1 and 4). The air passage S described above is formed between the fins 13-1 on one heat sink half body 11 and the fins 13-1 on the other heat sink half body 11. In this structure, the fins 13-1 can be cooled efficiently by air flowing through the air passage S.

Also, the support portion 12 has extended portions intersecting the first extended portion 12a, and fins 13 are formed on these two extended portions. In this example, as shown in FIG. 4, the support portion 12 has a second extended portion 12b intersecting the first extended portion 12a, and a third extended portion 12c intersecting the first extended portion 12a. In this example, the second extended portion 12b and the third extended portion 12c are orthogonal to the first extended portion 12a.

As mentioned above, two adjacent heat sinks 10 are arranged at a 90° angle with respect to each other. Therefore, the second extended portion 12b and the third extended portion 12c on one heat sink 10 of the two adjacent heat sinks 10 extend in direction X1-X2, and the second extended portion 12b and the third extended portion 12c on the other heat sink 10 extend in direction Y1-Y2 (see FIG. 2).

As shown in FIGS. 1-2, the second extended portion 12b extends in the opposite direction from the first extended portion 12a. In other words, the second extended portion 12b includes a portion extending towards the air passage S, and a portion extending in the opposite direction. Similarly, the third extended portion 12c extends in the opposite direction from the first extended portion 12a. In other words, the third extended portion 12c includes a portion extending towards the air passage S, and a portion extending in the opposite direction.

The support portion 12 in this example has two second extended portions 12b and two third extended portions 12c. The two second extended portions 12b are formed symmetrically with respect to the center of the first extended portion 12a. Similarly, the two third extended portions 12c are formed symmetrically with respect to the center of the first extended portion 12a. The two third extended portions 12c are formed at the two ends of the first extended portion 12a.

As shown in FIGS. 1-2, the second extended portions 12b and the third extended portions 12c, like the first extended portion 12a, are slender wall-like members which are erected on a plane parallel to the circuit board 90. A plurality of fins 13 extend from the side surface of a second extended portion 12b and are arranged in the direction of extension. The fins 13 on the second extended portion 12b extend opposite the fins 13 on the first extended portion 12a. In a third extended portion 12c, a plurality of fins 13 extend from the side surface of the third extended portion 12c and are arranged in the direction of extension. The fins 13 on the third extended portion 12c extend opposite the fins 13 on the second extended portion 12b.

As shown in FIG. 4, the second extended portions 12b on the two heat sink half bodies 11 are not linked to each other. Instead, an air passage S is formed between them. The third extended portions 12c on the two heat sink half bodies 11 are also not connected to each other. Here, too, an air passage S is formed between them. In this way, air can smoothly pass between the fins 13-1 formed on the first extended portion 12a and the fins 13 formed on the second extended portion 12b.

As shown in FIG. 4, two connecting holes H are formed some distance from each other in the first extended portion 12a. Two connecting holes H are also formed in the second extended portion 12b, and these are arranged opposite those in the first extended portion 12a with the first extended portion 12a interposed in between. In addition, connecting holes H are formed in the third extended portion 12c. In this way, connecting holes H are distributed throughout the support portion 12. In this way, the cooling function of the heat sink 10 does not depend as much on the heat pipes 31.

As mentioned above, the heat-transferring member 20 includes four heat-dissipating plates 21. In this example, the four heat-dissipating plates 21 are arranged in two rows and two columns (see FIG. 5). As shown in FIG. 1, a plurality of heat pipes 31 (eight in this example) connected to two adjacent heat-dissipating plates 21 are fixed to a single heat sink half body 11. In other words, eight heat pipes 31 pass through eight connecting holes H in each heat sink half body 11. In this way, two adjacent heat-dissipating plates 21 can be connected via a heat sink half body 11. Also, as mentioned above, two adjacent heat sinks 10 are arranged at a 90° angle with respect to each other in the circumferential direction with reference to the centerline C1. As a result, four heat-dissipating plates 21 are connected via a heat sink 10.

The cooling device 1 can be assembled in the following manner. First, the end portions of heat pipes 31 are fixed to four heat-transferring members 20. In other words, the end portions of the heat pipes 31 are inserted into holes formed in the sockets 22 of the heat-transferring members 20. The ends of the heat pipes 31 are fixed to the sockets 22 using soldering, an adhesive, or forced insertion. Four heat-transferring members 20 are arranged in two rows and two columns. Afterwards, the plurality of heat pipes 31 are inserted into the plurality of connecting holes H in the first heat sink 10. The heat sink 10 is then soldered or bonded to the heat pipes 31. Next, the second heat sink 10 is rotated 90° with respect to the first heat sink 10, and inserted into the plurality of heat pipes 31. The second heat sink 10 is then fixed to the heat pipes 31. The third heat sink 10 and the fourth heat sink 10 are inserted into the heat pipes 31 in the same manner.

As explained above, the cooling device 1 has a heat-transferring member 20 mounted on one side of a circuit board 90, a panel-shaped heat-generating body, and has a heat sink 10 arranged closer to the heat-transferring member 20 than the circuit board 90 in the thickness direction of the circuit board 90. The heat sink 10 has a plurality of fins 13 extending in the direction of the circuit board 90 with space formed between them. Also, the heat sink 10 includes a support portion 12 which extends in the arrangement direction of the fins 13, and which connects to and supports the plurality of fins 13. The cooling device 1 has a plurality of heat pipes 31 arranged at some distance from each other and connected to a heat-transferring member 20. Each heat pipe 13 extends in the thickness direction of the circuit board 90 and is connected to the support portion 12. In this way, heat can be transferred efficiently to the heat sink 10.

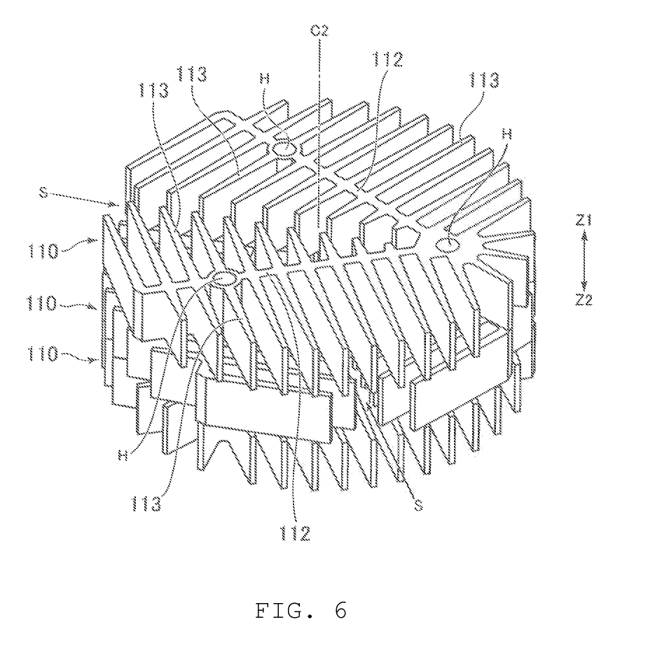

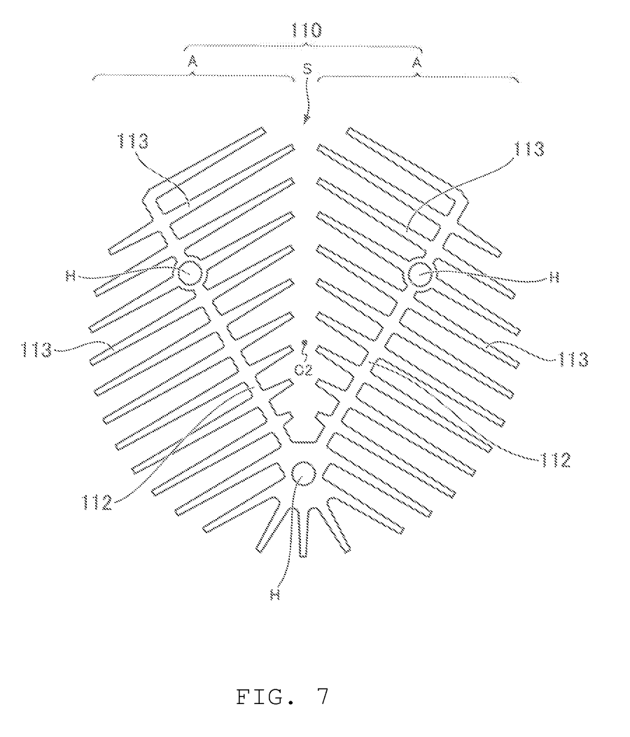

FIGS. 6-7 illustrate a modified example of heat sinks. The three heat sinks 110 shown in FIG. 6 are arranged opposite the circuit board with the heat-transferring member 20 interposed between them. These are arranged in the thickness direction of the circuit board (direction Z in FIG. 6). As shown in FIG. 7, each heat sink 110 has a plurality of fins 113 extending in the direction of the circuit board with space formed between them. Also, each heat sink 110 has a support portion 112 extending in the arrangement direction of the plurality of fins 113 and connected to them. Each heat sink 10 is composed of two half bodies (referred to as heat sink half portions A below), and each of the heat sink half portions A includes a support portion 112 and a plurality of fins 113. Two support portions 112 extend from their shared end portion and an acute angle (specifically, a 60° angle) is formed between them. The heat sink half portions A include a plurality of fins 113 extending towards the inside of the two support portions 112, and a plurality of fins 113 extending towards the outside of the two support portions 112. The fins 113 give the heat sink 110 a circular-shape overall. The two heat sink half portions A are connected by the shared end portion of the support portions 112.

A plurality of connecting holes H are formed in the two support portions 112 (three in this example). As in the cooling device 1, a heat-transferring column (for example, a heat pipe) is passed through each connecting hole H. In this way, the support portions 112 of the three heat sinks 110 are connected by a plurality of heat-transferring columns.

As shown in FIG. 7, an air passage S is formed between two heat sink half portions A which extends in the thickness direction of the circuit board and is linked to the outside of the heat sink 110. In this way, air can be sent to both heat sink half portions A via the air passage S. In this example, an air passage S is formed between fins 113 extending inward from one support portion 112 and fins 113 extending inward from another support portion 112. In this way, air can be sent to the fins 113.

As shown in FIG. 6, three heat sinks 110 are arranged so that two adjacent heat sinks 110 are offset in the circumferential direction with respect to the centerline C2. In this example, the two adjacent heat sinks 110 are offset 120° in the circumferential direction with respect to the centerline C2. As a result, the air passages S of two adjacent heat sinks 110 do not overlap in the thickness direction of the circuit board.

As mentioned above, a plurality of connecting holes H are formed in the support portion 112 for the insertion of heat pipes. As shown in FIG. 7, the positions of the connecting holes H are rotationally symmetrical with respect to the centerline C2. In other words, the connecting holes H are arranged on a circle centered on centerline C2 at the offset angle of two adjacent heat sinks 110 (120° in this example). Here, the three heat sinks 110 have the same shape, and each heat pipe is connected to the three heat sinks 110. In this example, connecting holes H are formed in the shared end of two support portions 112. Connecting holes H are also formed at the same positions on the opposite side of the support portions 112. In this way, three connecting holes H are positioned at the vertices of an equilateral triangle. This concludes the explanation of the heat sinks 110.

In the cooling device 1, the heat sink half bodies 11 of the heat sinks 10 all have the same shape. However, the heat sink half bodes 11 do not have to have the same shape. For example, the two heat sink half bodies constituting a single heat sink 10 can have different shapes.

While a preferred embodiment of the Present Disclosure is shown and described, it is envisioned that those skilled in the art may devise various modifications without departing from the spirit and scope of the foregoing Description and the appended Claims.

What is claimed is:

1. A cooling assembly, the cooling assembly comprising:
a heat-transferring member having first and second opposite sides, the first side of the heat-transferring member being configured for attachment to a heat-generating body;
a heat sink assembly, the heat sink assembly including first and second heat sinks provided in a stacked configuration whereby the first heat sink is positioned between the second side of the heat-transferring member and the second heat sink, each of the first and second heat sinks having first and second support portions, each of the first and second support portions having fins extending therefrom, wherein the second heat sink is provided at an offset angle relative to the first heat sink; and
a plurality of heat-transferring columns, each heat-transferring column extending from the second side of the heat-transferring member, each heat-transferring column configured to engage the heat sink assembly and to support the heat sink assembly relative to the heat-transferring member.

2. The cooling assembly of claim 1, wherein the first and second heat sinks are identical to one another.

3. The cooling assembly of claim 1, wherein the second heat sink is provided at an offset angle of 90° relative to the first heat sink.

4. The cooling assembly of claim 3, wherein the heat sink assembly further includes third and fourth heat sinks provided in a stacked configuration with the first and second heat sinks whereby the second heat sink is positioned between the first heat sink and the third heat sink and whereby the third heat sink is positioned between the second heat sink and the fourth heat sink, each of the third and fourth heat sinks having first and second support portions, each of the first and second support portions of the third and fourth heat sinks having fins extending therefrom, wherein the third heat sink is provided at an offset angle of 90° relative to the second heat sink and at an offset angle of 180° relative to the first sink, and wherein the fourth heat sink is provided at an offset angle of 90° relative to the third heat sink and at an offset angle of 270° relative to the first sink.

5. The cooling assembly of claim 4, wherein the first, second, third and fourth heat sinks are identical to each other.

6. The cooling assembly of claim 1, wherein the second heat sink is provided at an offset angle of 120° relative to the first heat sink.

7. The cooling assembly of claim 6, wherein the heat sink assembly further includes a third heat sink provided in a stacked configuration with the first and second heat sinks whereby the second heat sink is positioned between the first heat sink and the third heat sink, the third heat sink having first and second support portions, the first and second support portions of the third heat sink having fins extending therefrom, wherein the third heat sink is provided at an offset angle of 120° relative to the second heat sink and at an offset angle of 240° relative to the first heat sink.

8. The cooling assembly of claim 7, wherein the first, second and third heat sinks are identical to each other.

9. The cooling assembly of claim 1, wherein the first and second support portions are integrally formed.

10. The cooling assembly of claim 9, wherein the first and second support portions extend from a shared end portion such that an acute angle is formed between them.

11. The cooling assembly of claim 10, wherein a first set of fins extend toward an inside of the first and second support portions, and wherein a second set of fins extend toward an outside of the first and second support portions.

12. The cooling assembly of claim 11, wherein the first and second set of fins give each heat sink a circular-shape.

13. The cooling assembly of claim 10, wherein three heat-transferring columns are provided, and wherein each heat sink defines three holes, each hole configured to receive one of the three heat-transferring columns, and wherein a first one of the holes is provided through the first support portion, a second one of the holes is provided through the second support portion, and a third one of the holes is provided through the shared end portion.

14. The cooling assembly of claim 13, wherein the first, second and third holes are arranged along an imaginary circle centered on a centerline of the heat-transferring member.

15. The cooling assembly of claim 1, wherein the first and second support portions are separated from one another to define an air passage associated with the heat sink that extends through the heat sink.

16. The cooling assembly of claim 15, wherein each heat sink includes first and second halves, the first and second halves being spaced apart from each other to define the air passage associated with the heat sink that extends horizontally through the heat sink.

17. The cooling assembly of claim 16, wherein each support portion has a first extended portion and a plurality of second extended portions, the plurality of second extended portions extending orthogonally relative to the first extended portion.

18. The cooling assembly of claim 17, wherein four second extended portions are provided, a first one of the second extended portions being provided at a first end of the first extended portion, a second one of the second extended portions being provided proximate to the first end of the first extended portion, a third one of the second extended portions being provided at a second end of the first extended portion, and a fourth one of the second extended portions being provided proximate to the second end of the first extended portion.

19. The cooling assembly of claim 17, wherein a first set of fins extend from the first extended portion and a second set of fins extend from the plurality of second extended portions, the first set of fins extending orthogonally relative to the second set of fins.

20. The cooling assembly of claim 19, wherein the first and second sets of fins give each heat sink a circular-shape.

21. The cooling assembly of claim 17, wherein a first set of eight heat-transferring columns are provided, and wherein each heat sink defines a first set of eight holes, each hole of the first set configured to receive one of the eight heat-transferring columns of the first set, and wherein two of the holes of the first set are provided through the first extended portion of the first support portion, two of the holes of the first set are provided through the second extended portions of the first support portion, two of the holes of the first set are provided through the first extended portion of the second support portion, and two of the holes of the first set are provided through the second extended portions of the second support portion.

22. The cooling assembly of claim 21, wherein the eight holes of the first set are arranged along an imaginary first circle centered on the centerline of the heat-transferring member.

23. The cooling assembly of claim 22, wherein a second set of eight heat-transferring columns are provided, and wherein each heat sink defines a second set of eight holes, each hole of the second set configured to receive one of the eight heat-transferring columns of the second set, and wherein four of the holes of the second set are provided through the second extended portions of the first support portion, and four of the holes of the second set are provided through the second extended portions of the second support portion.

24. The cooling assembly of claim 23, wherein the eight holes of the second set are arranged along an imaginary second circle centered on the centerline of the heat-transferring member, and wherein the imaginary second circle has a larger diameter than the imaginary first circle.

25. The cooling assembly of claim 1, wherein the plurality of heat-transferring columns are arranged along an imaginary circle centered on a centerline of the heat-transferring member.

26. The cooling assembly of claim 1, wherein a first set of the plurality of heat-transferring columns are arranged along an imaginary first circle centered on a centerline of the heat-transferring member, and wherein a second set of the plurality of heat-transferring columns are arranged along an imaginary second circle centered on the center line of the heat-transferring member, and wherein the imaginary second circle has a larger diameter than the imaginary first circle.
